(19) United States
(12) Patent Application Publication
(10) Pub. No.: US 2026/0182461 A1
(43) Pub. Date: Jun. 25, 2026

(54) SEMICONDUCTOR PACKAGE

(71) Applicant: Samsung Electronics Co., Ltd., Suwon-si (KR)

(72) Inventors: Sanghyeon LEE, Suwon-si (KR); Taejun JEON, Suwon-si (KR)

(21) Appl. No.: 19/289,707

(22) Filed: Aug. 4, 2025

(30) Foreign Application Priority Data
Dec. 20, 2024 (KR) 10-2024-0192685

(51) Int. Cl. H10W 90/00; H10W 70/685; H10W 74/10; H10W 72/00; H10W 72/20; H10W 72/90; H10W 90/24

(52) U.S. Cl. CPC H10W 90/00; H10W 70/685; H10W 74/111; H10W 72/225; H10W 72/234; H10W 72/252; H10W 72/253; H10W 72/823; H10W 72/9445; H10W 90/24

(57) ABSTRACT

A semiconductor package includes a first semiconductor chip including first chip pads, a second semiconductor chip including second chip pads and stacked on the first semiconductor chip in a vertical direction, wherein the second semiconductor chip exposes a portion of the top surface of the first semiconductor chip, a mold layer covering the first and second semiconductor chips, a redistribution substrate on the mold layer, and a first conductive structure penetrating the mold layer in the vertical direction and electrically connected to a corresponding first chip pad among the plurality of first chip pads. The first conductive structure comprises barrel-shaped sections stacked in the vertical direction. Each barrel-shaped section has a convex circumferential side surface. The first conductive structure contains a first polymer matrix and first metal nanoparticles dispersed within the first polymer matrix.

### CROSS-REFERENCE TO RELATED APPLICATIONS

This U.S. non-provisional patent application claims priority under 35 U.S.C. §119 to Korean Patent Application No. 10-2024-0192685, filed on December 20, 2024, in the Korean Intellectual Property Office, the entire contents of which are hereby incorporated by reference.

### BACKGROUND OF THE INVENTION

The present disclosure relates to a semiconductor package.

Semiconductor packages include a semiconductor chip that is provided to be easily used as a part of an electronic product. The semiconductor packages may include a printed circuit board (PCB) and a semiconductor chip, which is mounted on the PCB and is electrically connected to the PCB using bonding wires or bumps. With development of the electronics industry, many studies are being conducted to improve reliability of the semiconductor packages and to reduce a size of the semiconductor package.

### SUMMARY

An embodiment of the inventive concept provides a semiconductor package with a small size.

An embodiment of the inventive concept provides a semiconductor package fabricated by a simplified process.

According to an aspect of the present disclosure, a semiconductor package includes a first semiconductor chip including a plurality of first chip pads, a second semiconductor chip including a plurality of second chip pads and stacked on the first semiconductor chip in a vertical direction perpendicular to a top surface of the first semiconductor chip, wherein the second semiconductor chip exposes a portion of the top surface of the first semiconductor chip, a mold layer covering the first semiconductor chip and the second semiconductor chip, a redistribution substrate on the mold layer, and a first conductive structure penetrating the mold layer in the vertical direction and electrically connected to a corresponding first chip pad among the plurality of first chip pads. The first conductive structure comprises a plurality of barrel-shaped sections stacked in the vertical direction. Each barrel-shaped section of the plurality of barrel-shaped sections has a convex circumferential side surface. The first conductive structure contains a first polymer matrix and a plurality of first metal nanoparticles dispersed within the first polymer matrix.

According to an aspect of the present disclosure, a semiconductor package includes a chip stack including a first semiconductor chip, a mold layer covering the chip stack, a redistribution substrate including a plurality of insulating layers on the mold layer and a plurality of redistribution patterns in the plurality of insulating layers, and a first conductive structure extending lengthwise in a vertical direction perpendicular to a top surface of the first semiconductor chip, wherein the first conductive structure penetrates the mold layer and electrically connects the redistribution substrate to the first semiconductor chip. The first conductive structure contains a first polymer matrix and a plurality of first metal nanoparticles dispersed in the first polymer matrix. Each redistribution pattern of the plurality of redistribution patterns contains a second polymer matrix and a plurality of second metal nanoparticles dispersed in the second polymer matrix.

According to an aspect of the present disclosure, a semiconductor package includes a first semiconductor chip including a plurality of first chip pads, a second semiconductor chip including a plurality of second chip pads and stacked on the first semiconductor chip in a vertical direction perpendicular to a top surface of the first semiconductor chip, wherein the second semiconductor chip exposes a portion of the top surface of the first semiconductor chip, a mold layer covering the first semiconductor chip and the second semiconductor chip, a redistribution substrate including a plurality of insulating layers on the mold layer and a plurality of redistribution patterns in the plurality of insulating layers, a first conductive structure penetrating the mold layer in the vertical direction and electrically connected to a corresponding first chip pad among the plurality of first chip pads, and a plurality of connection terminals on the redistribution substrate. A side surface of the first conductive structure comprises a plurality of concave portions and a plurality of convex portions. Each concave portion of the plurality of concave portions and each convex portion of the plurality of convex portions are alternately arranged in the vertical direction. The first conductive structure contains a first polymer matrix and a plurality of first metal nanoparticles dispersed in the first polymer matrix. Each redistribution pattern of the plurality of redistribution patterns contains a second polymer matrix and a plurality of second metal nanoparticles dispersed in the second polymer matrix.

### BRIEF DESCRIPTION OF THE DRAWINGS

FIG. 1 is a plan view illustrating a semiconductor package according to an embodiment of the inventive concept.

FIG. 2 is a sectional views taken along line A-A' of FIG. 1.

FIGS. 3A and 3B are enlarged views illustrating portions ‘P1’ and ‘P2’, respectively, of FIG. 2.

FIG. 4 and FIGS. 5 to 11 are a plan view and sectional views illustrating a method of fabricating a semiconductor package, according to an embodiment of the inventive concept.

### DETAILED DESCRIPTION

Example embodiments of the inventive concepts will now be described more fully with reference to the accompanying drawings, in which example embodiments are shown.

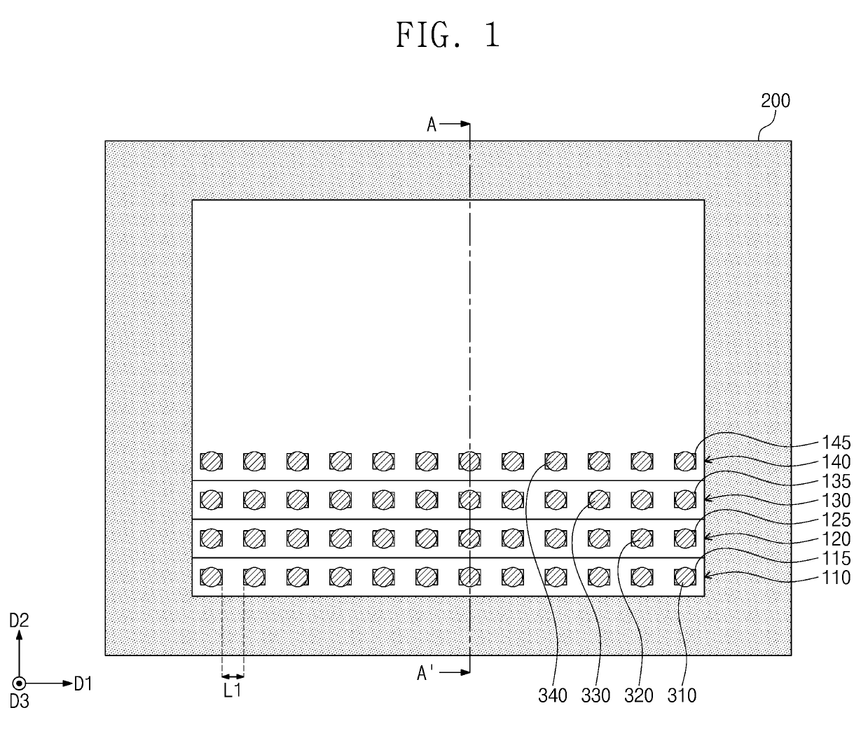

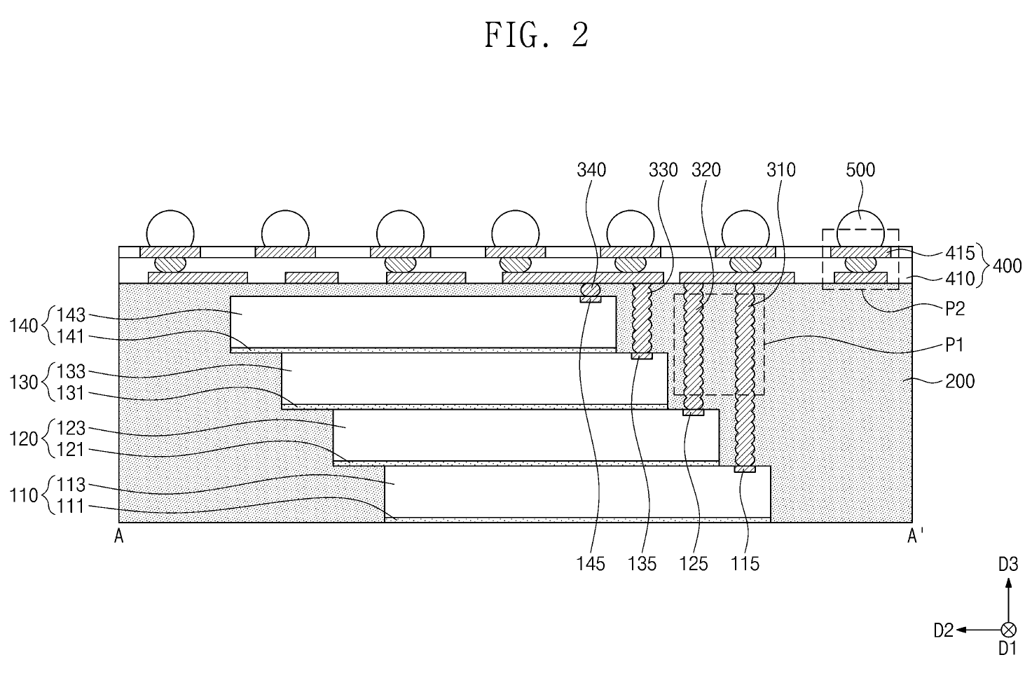

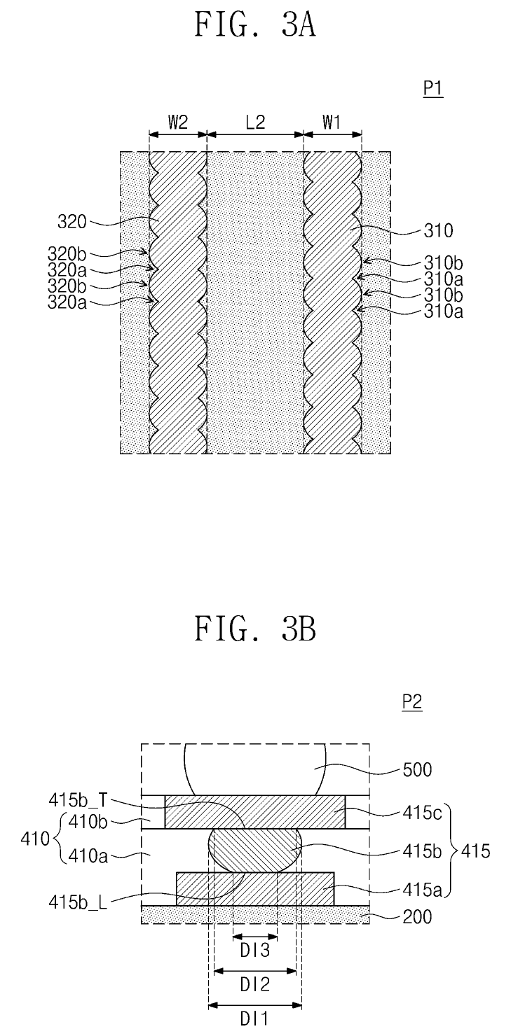

FIG. 1 is a plan view illustrating a semiconductor package according to an embodiment of the inventive concept. FIG. 2 is a sectional views taken along line A-A' of FIG. 1. FIGS. 3A and 3B are enlarged views illustrating portions ‘P1’ and ‘P2’ of FIG. 2, respectively.

Referring to FIGS. 1 and 2, a semiconductor package may include a chip stack including first to fourth semiconductor chips 110, 120, 130, and 140, a mold layer 200, a plurality of conductive structures 310, 320, 330, and 340, and a redistribution substrate 400.

The chip stack may include a first semiconductor chip 110, a second semiconductor chip 120, a third semiconductor chip 130, and a fourth semiconductor chip 140. The first to fourth semiconductor chips 110, 120, 130, and 140 may include die adhesive layers 111, 121, 131, and 141 and semiconductor dies 113, 123, 133, and 143, respectively. For example, the first semiconductor chip 110 may include a first die adhesive layer 111 and a first semiconductor die 113, and the second semiconductor chip 120 may include a second die adhesive layer 121 and a second semiconductor die 123. Similarly, the third semiconductor chip 130 may include a third die adhesive layer 131 and a third semiconductor die 133, and the fourth semiconductor chip 140 may include a fourth die adhesive layer 141 and a fourth semiconductor die 143. The first to fourth die adhesive layers 111, 121, 131, and 141 may be disposed below bottom surfaces of the first to fourth semiconductor dies 113, 123, 133, and 143, respectively. In an embodiment, the first to fourth die adhesive layers 111, 121, 131, and 141 may include an insulating adhesive material. In an embodiment, a memory device may be integrated in each of the first to fourth semiconductor dies 113, 123, 133, and 143. The number of semiconductor chips stacked in the chip stack is not limited to four as shown in FIG. 2. In an embodiment, two or three semiconductor chips, or five or more semiconductor chips may be stacked in the chip stack. In the present specification, a first direction D1 (i.e., a first horizontal direction) and a second direction D2 (i.e., a second horizontal direction) may be parallel to a top surface of the first semiconductor chip 110, and a third direction D3 (i.e., a vertical direction) may be perpendicular to the top surface of the first semiconductor chip 110.

The first to fourth semiconductor chips 110, 120, 130, and 140 may be sequentially stacked to form a stepwise structure in the second direction D2. For example, the second semiconductor chip 120 may be stacked on the first semiconductor chip 110 and may be offset from the first semiconductor chip 110 in the second direction D2, the third semiconductor chip 130 may be stacked on the second semiconductor chip 120 and may be offset from the second semiconductor chip 120 in the second direction D2, and the fourth semiconductor chip 140 may be stacked on the third semiconductor chip 130 and may be offset from the third semiconductor chip 130 in the second direction D2.

The first to fourth semiconductor chips 110, 120, 130, and 140 may include chip pads 115, 125, 135, and 145, respectively. The chip pads 115 may be disposed at a portion of the top surface of the first semiconductor chip 110, which does not overlap the second semiconductor chip 120. Similarly, the chip pads 125 may be disposed at a portion of a top surface of the second semiconductor chip 120, which does not overlap the third semiconductor chip 130, and chip pads 135 may be disposed at a portion of a top surface of the third semiconductor chip 130, which does not overlap the fourth semiconductor chip 140. In an embodiment, the chip pads 115, 125, 135, and 145 of the first to fourth semiconductor chips 110, 120, 130, and 140 may include at least one of metallic materials (e.g., copper, tungsten, and/or titanium).

The chip pads 115 of the first semiconductor chip 110 may be spaced apart from each other in the first direction D1. Adjacent ones of the chip pads 115 of the first semiconductor chip 110 may be spaced apart from each other by a first distance L1. Similarly, the chip pads 125 of the second semiconductor chip 120 may be spaced apart from each other in the first direction D1 by the first distance L1, the chip pads 135 of the third semiconductor chip 130 may be spaced apart from each other in the first direction D1 by the first distance L1, and the chip pads 145 of the fourth semiconductor chip 140 may be spaced apart from each other in the first direction D1 by the first distance L1. In an embodiment, the first distance L1 may have a value in a range of 10 μm to 40 μm.

The mold layer 200 may cover the chip stack including the first to fourth semiconductor chips 110, 120, 130, and 140. The mold layer 200 may cover top and side surfaces of the first to fourth semiconductor chips 110, 120, 130, and 140. In an embodiment, the mold layer 200 may include a material (e.g., an epoxy molding compound) or an adhesive material.

The conductive structures 310, 320, 330, and 340 may connect the first to fourth semiconductor chips 110, 120, 130, and 140 to the redistribution substrate 400, respectively. The conductive structures 310, 320, 330, and 340 may be provided to penetrate the mold layer 200 and to electrically connect the chip pads 115, 125, 135, and 145 of the first to fourth semiconductor chips 110, 120, 130, and 140 to the redistribution substrate 400. Each of the first to third conductive structures 310, 320, and 330 may extend lengthwise in the third direction D3. In an embodiment, the fourth conductive structure 340 may be formed similarly to the first to third conductive structures 310, 320, and 330, and may extend lengthwise in the third direction D3.

The conductive structures 310, 320, 330, and 340 may include first conductive structures 310 electrically connected to the first semiconductor chip 110, second conductive structures 320 electrically connected to the second semiconductor chip 120, third conductive structures 330 electrically connected to the third semiconductor chip 130, and fourth conductive structures 340 electrically connected to the fourth semiconductor chip 140. The first conductive structures 310 may be electrically connected to the chip pads 115, respectively, of the first semiconductor chip 110, and the second conductive structures 320 may be electrically connected to the chip pads 125, respectively, of the second semiconductor chip 120. Similarly, the third conductive structures 330 may be electrically connected to the chip pads 135, respectively, of the third semiconductor chip 130, and the fourth conductive structures 340 may be electrically connected to the chip pads 145, respectively, of the fourth semiconductor chip 140.

Each of the first conductive structures 310 may vertically overlap a corresponding chip pad of the chip pads 115 of the first semiconductor chip 110, and each of the second conductive structures 320 may vertically overlap a corresponding chip pad of the chip pads 125 of the second semiconductor chip 120. Similarly, each of the third conductive structures 330 may vertically overlap a corresponding chip pad of the chip pads 135 of the third semiconductor chip 130, and each of the fourth conductive structures 340 may vertically overlap a corresponding chip pad of the chip pads 145 of the fourth semiconductor chip 140. In other words, the first conductive structure 310 may vertically overlap a corresponding chip pad of the chip pads 115 of the first semiconductor chip 110, and the second conductive structure 320 may vertically overlap a corresponding chip pad of the chip pads 125 of the second semiconductor chip 120.

A vertical length, measured in the third direction D3, of each of the first conductive structures 310 may be larger than a vertical length, measured in the third direction D3, of each of the second conductive structures 320. The vertical length, measured in the third direction D3, of each of the second conductive structures 320 may be larger than a vertical length, measured in the third direction D3, of each of the third conductive structures 330. The vertical length, measured in the third direction D3, of each of the third conductive structures 330 may be larger than a vertical length, measured in the third direction D3, of each of the fourth conductive structures 340. The first to fourth conductive structures 310, 320, 330, and 340 may have top surfaces that are coplanar with a top surface of the mold layer 200.

Referring to FIGS. 2 and 3A, the first and second conductive structures 310 and 320 may include a side surface having concave portions 310a and 320a and convex portions 310b and 320b. On the side surface of each of the first conductive structures 310, the concave portions 310a and the convex portions 310b may be alternately disposed in the third direction D3. A horizontal width of the concave portion 310a may be smaller than a horizontal width of the convex portions 310b adjacent to the concave portion 310a. As an example, the side surface of the first conductive structure 310 may have a wavy or wave-like shape, when viewed in a sectional view. Similarly, on the side surface of each of the second conductive structures 320, concave portions 320a and convex portions 320b may be alternately disposed in the third direction D3. Although not shown in FIG. 3A, the third conductive structures 330 may include concave portions and convex portions which are formed on side surfaces thereof. In an embodiment, each of the first conductive structure 310 and the second conductive structure 320 may include a plurality of barrel-shaped sections stacked on each other in the third direction D3. The plurality of barrel-shaped sections may have uniform height and width, or at least one of the barrel-shaped sections may differ from the others in height or width. Similarly, the third conductive structure 330 may include a plurality of barrel-shaped sections stacked on each other in the vertical direction. Each barrel-shaped section of the plurality of barrel-shaped sections has a convex circumferential side surface. The plurality of barrel-shaped sections may have uniform height and width, or at least one of the plurality of barrel-shaped sections may differ from the others in height or width.

A horizontal width of the concave portion 320a may be smaller than a horizontal width of the convex portions 320b adjacent to the concave portion 320a. In an embodiment, the side surfaces of the first to third conductive structures 310, 320, and 330 may have a wavy or wave-like shape, when viewed in a sectional view. The concave and convex portions 310a and 310b of the first conductive structures 310 and the concave and convex portions 320a and 320b of the second conductive structures 320 may be covered with the mold layer 200. In an embodiment, the mold layer 200 may contact the concave and convex portions 310a and 310b of the first conductive structures 310 and the concave and convex portions 320a and 320b of the second conductive structures 320. The side surfaces of the first to third conductive structures 310, 320, and 330 may have a profile that is formed by the fabrication method according to an embodiment of the inventive concept.

The fourth conductive structures 340 may have a rounded side surface as shown in FIG. 2, but the inventive concept is not limited to this example. In an embodiment, each of the fourth conductive structures 340 may have a plurality of concave portions and a plurality of convex portions, as described with reference to the first to third conductive structures 310, 320, and 330. In an embodiment, each of the fourth conductive structures 340 may include a plurality of barrel-shaped sections stacked on each other in the third direction D3. Each barrel-shaped section of the plurality of barrel-shaped sections has a convex circumferential side surface. The plurality of barrel-shaped sections of each of the fourth conductive structures 340 may have uniform height and width, or at least one of the barrel-shaped sections may differ from the others in height or width.

The largest horizontal width W1, measured in the second direction D2, of the first conductive structure 310 may have a value in a range of 10 μm to 30 μm. In an embodiment, the largest horizontal width W1 of the first conductive structure 310 may mean the largest value of the horizontal widths of the concave and convex portions 310a and 310b of the first conductive structure 310. Similarly, the largest horizontal width W2, in the second direction D2, of the second conductive structure 320 may have a value in a range of 10 μm to 30 μm. In an embodiment, the largest horizontal width W2 of the second conductive structure 320 may mean the largest value of the horizontal widths of the concave and convex portions 320a and 320b of the second conductive structure 320. The first and second conductive structures 310 and 320, which face each other in the second direction D2, may be spaced apart from each other by a second pitch L2. In an embodiment, the second pitch L2 may correspond to a shortest distance between the first and second conductive structures 310 and 320. In an embodiment, the largest horizontal width W1, measured in the second direction D2, of the first conductive structure 310 may correspond to the largest width of a barrel-shaped section of the plurality of barrel-shaped sections in the first conductive structure 310. In an embodiment, the largest horizontal width W2 of the second conductive structure 320 may correspond to the largest width of a barrel-shaped section of the plurality of barrel-shaped sections in the second conductive structure 320.

In the first conductive structure 310, the concave portions 310a are illustrated to have the same horizontal width, and the convex portions 310b are illustrated to have the same horizontal width. The inventive concept is not limited to this example. For example, the horizontal widths of the concave portions 310a may be different from each other, and the horizontal widths of the convex portions 310b may be different from each other. In an embodiment, the horizontal widths of the plurality of barrel-shaped sections in the first conductive structure 310 may be the same as each other. However, the present disclosure is not limited thereto. In an embodiment, a horizontal width of at least one of the plurality of barrel-shaped sections in the first conductive structure 310 may differ from horizontal widths of others. Similarly, the horizontal widths of the plurality of barrel-shaped sections in the second conductive structure 320 may have the same as each other or at least one of the plurality of barrel-shaped sections in the second conductive structure 320 may differ from horizontal widths of others.

Each of the first to fourth conductive structures 310, 320, 330, and 340 may contain a first metal and a first polymer. In an embodiment, the first metal may include one of copper (Cu), silver (Ag), and gold (Au), and the first polymer may include at least one of polyurethane (PU), polyacrylate, polyethylene glycol (PEG), and polyvinyl alcohol (PVA). In each of the first to fourth conductive structures 310, 320, 330, and 340, the content of the first polymer may have a value in a range of 0.1 wt% to 10 wt%. In an embodiment, each of the first to fourth conductive structures 310, 320, 330, and 340 may contain the first metal as a plurality of first metal nanoparticles and the first polymer as a first polymer matrix. For example, the plurality of first metal nanoparticles may be dispersed within the first polymer matrix. The polymer matrix may serve as a carrier and stabilizer for the plurality of metal nanoparticles dispersed therein. In an embodiment, each first metal nanoparticle of the first metal nanoparticles may include one of copper (Cu), silver (Ag), and gold (Au), and the first polymer matrix may include at least one of polyurethane (PU), polyacrylate, polyethylene glycol (PEG), and polyvinyl alcohol (PVA). In each of the first to fourth conductive structures 310, 320, 330, and 340, the content of the first polymer matrix may have a range of 0.1 wt% to 10 wt%.

Referring to FIGS. 2 and 3B, the redistribution substrate 400 may include insulating layers 410 and redistribution patterns 415. The redistribution patterns 415 may be electrically connected to the conductive structures 310, 320, 330, and 340. The insulating layers 410 may include a first insulating layer 410a and a second insulating layer 410b sequentially stacked on the mold layer 200. In an embodiment, the first and second insulating layers 410a and 410b may include an organic material (e.g., a photoimageable dielectric (PID) material). The photoimageable insulating material may include at least one of polymers (e.g., photoimageable polyimide, polybenzoxazole, phenol-based polymer, and benzocyclobutene-based polymer).

The redistribution patterns 415 may include first redistribution lines 415a, first redistribution vias 415b, and second redistribution lines 415c. Although not shown in FIG. 2, insulating layers may be further disposed on the first and second insulating layers 410a and 410b, and redistribution lines and redistribution vias may be further disposed in the insulating layers.

The first redistribution lines 415a may be disposed in the first insulating layer 410a and may be in contact with top surfaces of the first to fourth conductive structures 310, 320, 330, and 340 and/or a top surface of the mold layer 200. Bottom surfaces of the first redistribution lines 415a may be parallel to the top surface of the first semiconductor chip 110.

The second redistribution lines 415c may be disposed on the first redistribution lines 415a. The second redistribution lines 415c may be disposed in the second insulating layer 410b. Bottom surfaces of the second redistribution lines 415c may be parallel to the top surface of the first semiconductor chip 110.

The first redistribution vias 415b may be disposed between the first redistribution lines 415a and the second redistribution lines 415c. The first redistribution vias 415b may be electrically connected to the first redistribution lines 415a and the second redistribution lines 415c. Each of the first redistribution vias 415b may have a top end 415b_T, which is in contact with a corresponding one of the second redistribution lines 415c, and a bottom end 415b_L, which is in contact with a corresponding one of the first redistribution lines 415a. Each of the first redistribution vias 415b may have the largest width DI1, between the top end 415b_T in contact with the second redistribution line 415c and the bottom end 415b_L in contact with the first redistribution line 415a. In other words, the largest width DI1 may be larger than a width DI2 of the top end 415b_T or a width DI3 of the bottom end 415b_L. In an embodiment, the largest width DI1 may have a value in a range of 10 μm to 30 μm. The largest width DI1 may be smaller than the largest width of each of connection terminals 500 to be described below. In an embodiment, each of the first redistribution vias 415b may have a rounded side surface connecting the top end 415b_T and the bottom end 415b_L. Each of the top end 415b_T and the bottom end 415b_L may be a flat surface parallel to the top surface of the first semiconductor chip 110.

The first redistribution vias 415b may be disposed in the first insulating layer 410a. A top surface of each of the first redistribution vias 415b may be coplanar with a top surface of the first insulating layer 410a.

Each of the redistribution patterns 415 may include a second metal and a second polymer. As an example, the second metal and the second polymer may be the same as the first metal and the first polymer, respectively, but the inventive concept is not limited to this example. In an embodiment, the second metal may include one of copper (Cu), silver (Ag), and gold (Au), and the second polymer may include at least one of polyurethane (PU), polyacrylate, polyethylene glycol (PEG), and polyvinyl alcohol (PVA). In each of the redistribution patterns 415, the second polymer may have a content in a range of 0.1 wt% to 10 wt%. In an embodiment, each of the redistribution patterns 415 may include the second polymer as a second polymer matrix and the second metal as a plurality of second metal nanoparticles dispersed within the second polymer matrix. In an embodiment, each second metal nanoparticle of the plurality of second metal nanoparticles may include one of copper (Cu), silver (Ag), and gold (Au), and the second polymer matrix may include at least one of polyurethane (PU), polyacrylate, polyethylene glycol (PEG), and polyvinyl alcohol (PVA). In each of the redistribution patterns 415, the second polymer matrix may have a content in a range of 0.1 wt% to 10 wt%.

Connection terminals 500 may be disposed on the redistribution substrate 400. The connection terminals 500 may be electrically connected to the second redistribution lines 415c. The largest width of each of the connection terminals 500 may be larger than the largest width of the first redistribution via 415b. The largest width of each of the connection terminals 500 may mean the largest width in a horizontal direction. In an embodiment, each of the connection terminals 500 may be formed of or include tin (Sn), bismuth (Bi), lead (Pb), silver (Ag), or an alloy thereof. Each of the connection terminals 500 may be provided in the form of a solder ball.

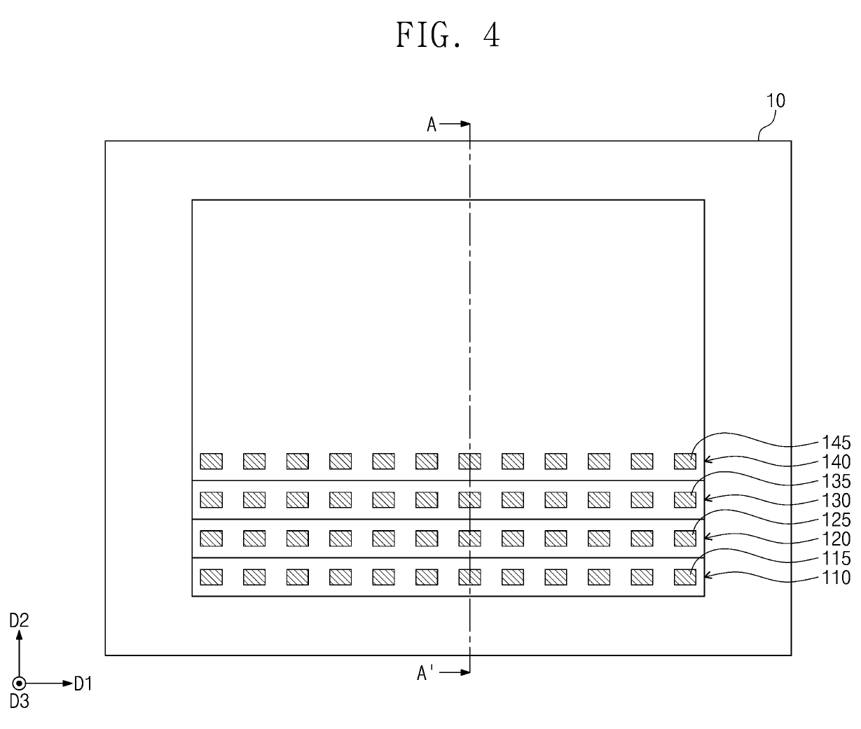

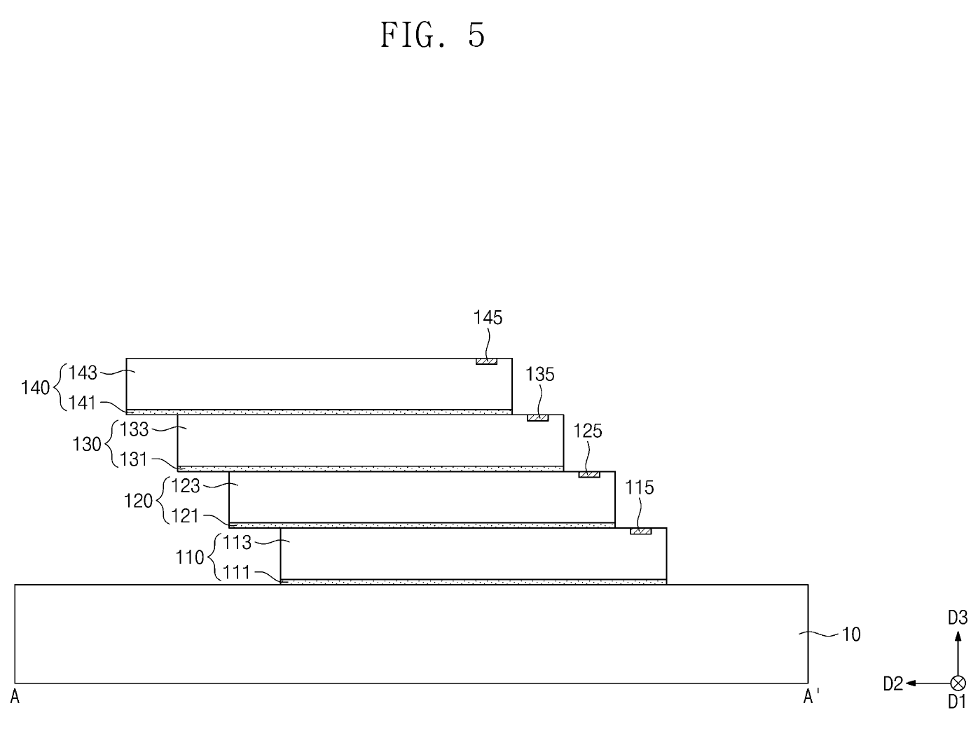

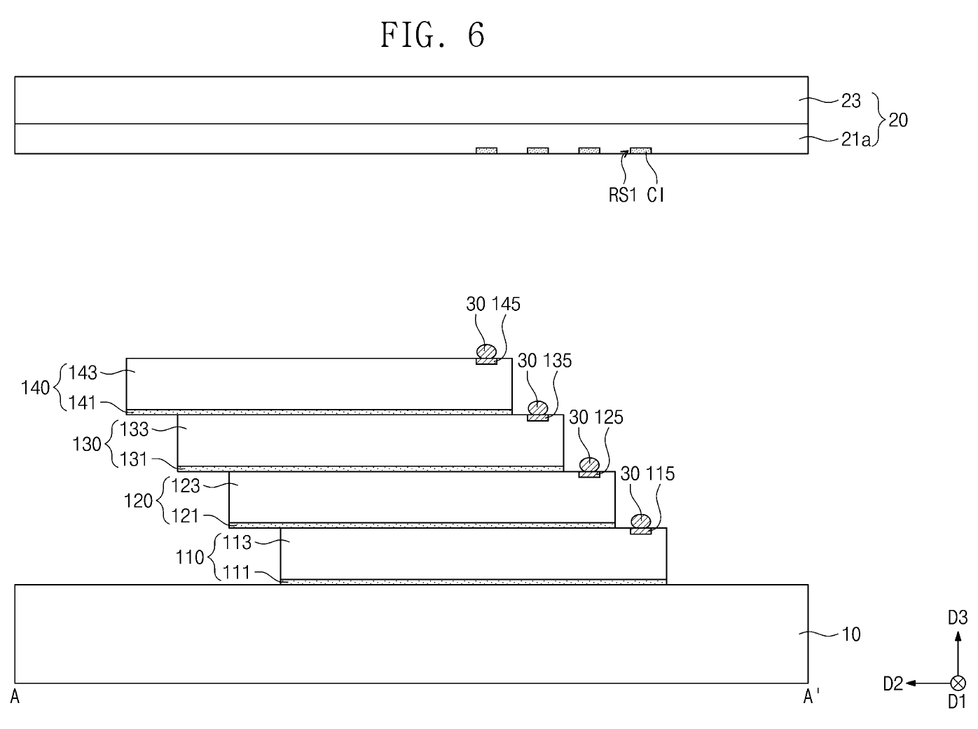

FIG. 4 and FIGS. 5 to 11 are a plan view and sectional views illustrating a method of fabricating a semiconductor package, according to an embodiment of the inventive concept. FIG. 5 is a sectional view taken along line A-A' of FIG. 4, and FIGS. 6 to 11 may correspond to FIG. 5.

Referring to FIGS. 4 and 5, a carrier substrate 10 may be provided. An adhesive layer (not shown) or an adhesive tape (not shown) may be provided on the carrier substrate 10.

A chip stack including first to fourth semiconductor chips 110, 120, 130, and 140 may be formed on the carrier substrate 10. In the chip stack, the first to fourth semiconductor chips 110, 120, 130, and 140 may be stacked on each other in the third direction D3. The stacking of the first to fourth semiconductor chips 110, 120, 130, and 140 may include stacking the first semiconductor chip 110 on the carrier substrate 10, stacking the second semiconductor chip 120 on the first semiconductor chip 110, stacking the third semiconductor chip 130 on the second semiconductor chip 120, and stacking the fourth semiconductor chip 140 on the third semiconductor chip 130. The first to fourth semiconductor chips 110, 120, 130, and 140 may be fastened to the carrier substrate 10 by die adhesive layers 111, 121, 131, and 141 provided under bottom surfaces of the first to fourth semiconductor chips 110, 120, 130, and 140.

The first to fourth semiconductor chips 110, 120, 130, and 140 may be stacked in a stepwise manner. The first to fourth semiconductor chips 110, 120, 130, and 140 may be offset from each other in the second direction D2, and top surfaces of the first to third semiconductor chips 110, 120, and 130 may be partially exposed. Chip pads 115, 125, and 135 of the first to third semiconductor chips 110, 120, and 130 may be disposed at the exposed top surfaces of the first to third semiconductor chips 110, 120, and 130.

Referring to FIG. 6, a semiconductor manufacturing apparatus 20 may be disposed over the first to fourth semiconductor chips 110, 120, 130, and 140. The semiconductor manufacturing apparatus 20 may include a first mask pattern 21a and a printing apparatus 23.

In an embodiment, the printing apparatus 23 may be a thermal ultrasonic printing apparatus. For example, the printing apparatus 23 may be configured to disperse a conductive ink (not shown) in the printing apparatus 23 using an ultrasonic wave. The printing apparatus 23 may discharge the conductive ink and thermally harden the conductive ink CI discharged. The conductive ink CI discharged from the printing apparatus 23 may pass through the first mask pattern 21a and may be sprayed. As an example, the conductive ink CI may contain a first metal, a first polymer, and solvent. In an embodiment, the first metal may include one of copper (Cu), silver (Ag), and gold (Au), and the first polymer may include at least one of polyurethane (PU), polyacrylate, polyethylene glycol (PEG), and polyvinyl alcohol (PVA). For example, the first metal may be dispersed as metal nanoparticles in the first polymer. In an embodiment, the solvent may include one of inorganic solvent and organic solvent. The first polymer may allow metal nanoparticles of the first metal in the conductive ink CI to be uniformly dispersed without clustering together. The metal nanoparticles may be electrically connected to one another to form a continuous conductive path that allows current to flow. Each of the metal nanoparticles may have a diameter ranged from 10nm to 1μm.

In an embodiment, the first mask pattern 21a may be a stencil mask. The first mask pattern 21a may be molded to be able to selectively discharge the conductive ink CI to certain regions. For example, the first mask pattern 21a may be molded to have a first recess portion RS1 at a specific position. As an example, the first recess portion RS1 may be a hole connected to the printing apparatus 23. The first recess portion RS1 of the first mask pattern 21a may be formed to correspond to chip pads 115, 125, 135, and 145 of the first to fourth semiconductor chips 110, 120, 130, and 140, and the first recess portion RS1 may vertically overlap the chip pads 115, 125, 135, and 145.

The conductive ink CI passing through the first recess portion RS1 may be sprayed onto the chip pads 115, 125, 135, and 145 of the first to fourth semiconductor chips 110, 120, 130, and 140. In an embodiment, the printing apparatus 23 may discharge the conductive ink CI in the form of droplets through the first recess portion RS1 toward the chip pads 115, 125, 135, and 145 of the first through fourth semiconductor chips 110, 120, 130, and 140, respectively. Thus, a conductive solder 30 may be formed on the chip pads 115, 125, 135, and 145.

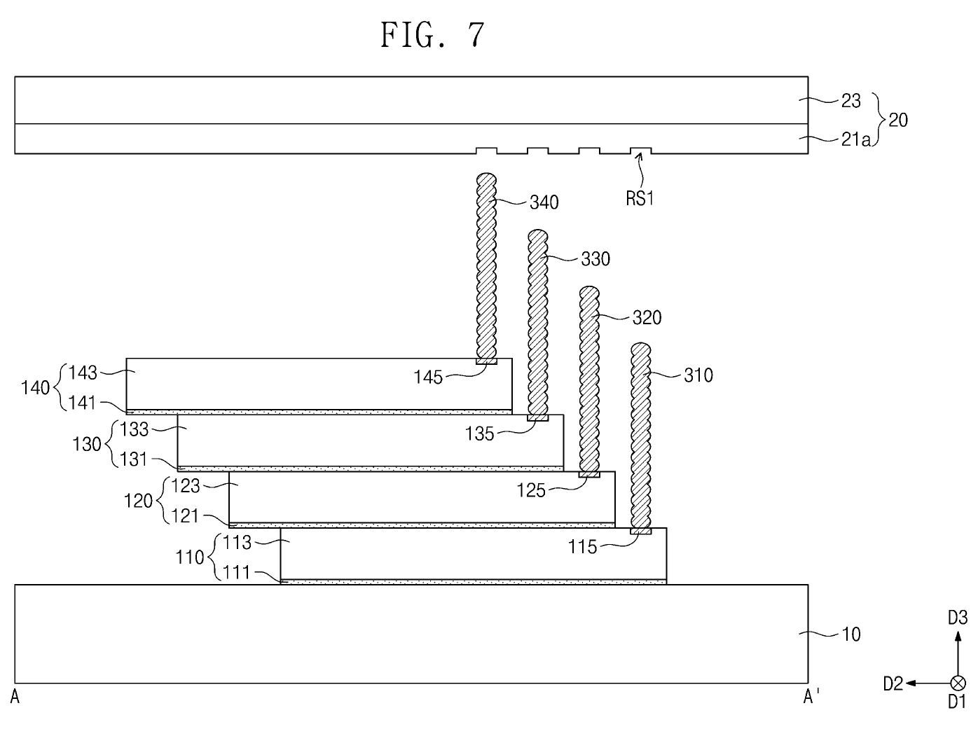

Referring to FIGS. 6 and 7, first to fourth conductive structures 310, 320, 330, and 340 may be formed by consecutively spraying the conductive inks CI on the conductive solders 30. In an embodiment, the printing apparatus 23 may consecutively discharge droplets of the conductive ink CI toward the chip pads 115, 125, 135, and 145 of the first through fourth semiconductor chips 110, 120, 130, and 140 to form the first to fourth conductive structures 310, 320, 330, and 340, respectively. The first conductive structures 310 may be respectively formed on the chip pads 115 of the first semiconductor chip 110, and the second conductive structures 320 may be respectively formed on the chip pads 125 of the second semiconductor chip 120. The third conductive structures 330 may be respectively formed on the chip pads 135 of the third semiconductor chip 130, and the fourth conductive structures 340 may be respectively formed on the chip pads 145 of the fourth semiconductor chip 140. As time passes, the solvents in the first to fourth conductive structures 310, 320, 330, and 340 may be evaporated, and thus, the first to fourth conductive structures 310, 320, 330, and 340 may be hardened. For example, after the evaporation of the solvents, the first polymer may be hardened to from a first polymer matrix in which the metal nanoparticles of the first metal in the conductive ink CI is dispersed in the first polymer matrix. The metal nanoparticles of the first metal in the polymer matrix may be connected to one another to allow a current flow through the first to fourth conductive structures 310, 320, 330, and 340.

In the case where a capillary apparatus is used to form wires that are electrically connected to the chip pads 115 of the first semiconductor chip 110, due to a thickness of the capillary apparatus and a thickness of the wire, there may be a requirement for the minimum pitch between the chip pads 115.

However, in a semiconductor package according to an embodiment of the inventive concept, a printing method may be used to form the conductive structures 310, 320, 330, and 340, which are respectively connected to the chip pads 115, 125, 135, and 145 arranged at a relatively small pitch. For example, the chip pads 115 may be arranged in the first direction D1 at a first pitch, which may be minimized such that adjacent droplets of the conductive ink CI in the first direction D1 do not contact each other. By adjusting the droplet width of the conductive ink CI, the first pitch between adjacent chip pads 115 in the first direction D1 may be further reduced. Similarly, pitches, in the first direction D1, of the chip pads 125, 135, and 145 may be minimized. Because the chip pads 115, 125, 135, and 145 can be arranged at a relatively small pitch when the conductive structures 310, 320, 330, and 340 are formed on the chip pads 115, 125, 135, and 145, respectively, using droplets of the conductive ink CI, the size of each of the semiconductor chips 110, 120, 130, and 140 may be reduced, thereby contributing to a reduction in the overall size of the semiconductor package.

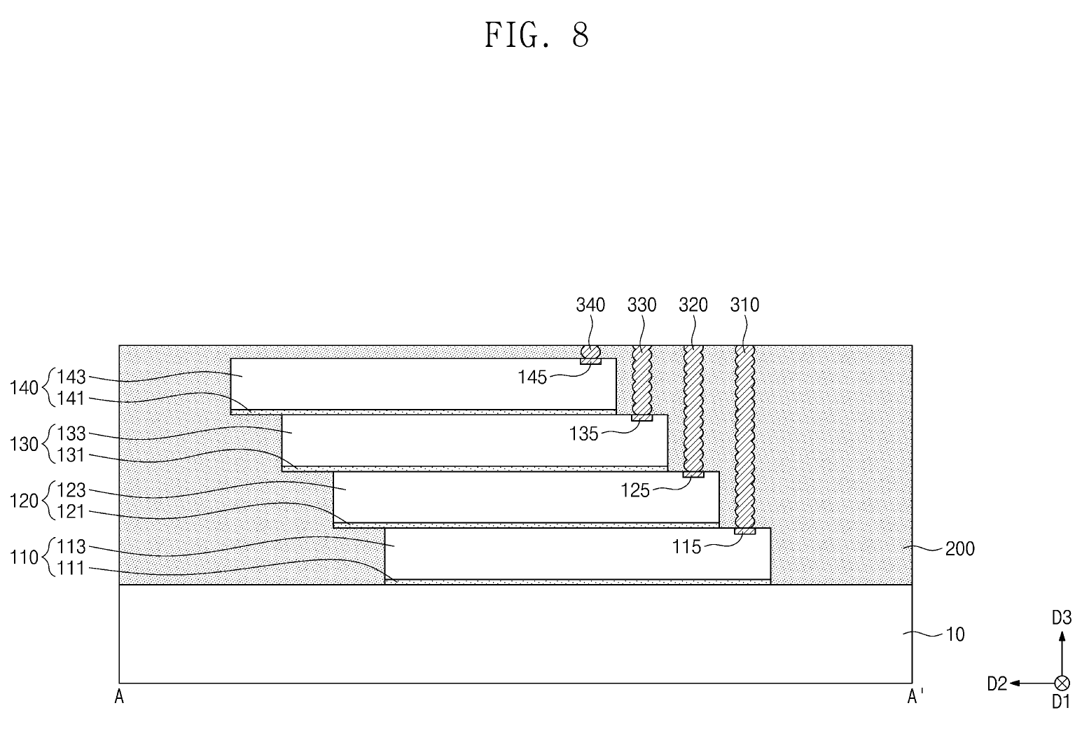

Referring to FIG. 8, the semiconductor manufacturing apparatus 20 may be removed. Next, a mold layer 200 may be formed to cover the first to fourth semiconductor chips 110, 120, 130, and 140 and the first to fourth conductive structures 310, 320, 330, and 340. A grinding process may be performed to remove upper portions of the first to fourth conductive structures 310, 320, 330, and 340 and an upper portion of the mold layer 200. Accordingly, after the griding process is completed, the mold layer 200 may have a top surface that is coplanar with a top surface of each of the first to fourth conductive structures 310, 320, 330, and 340.

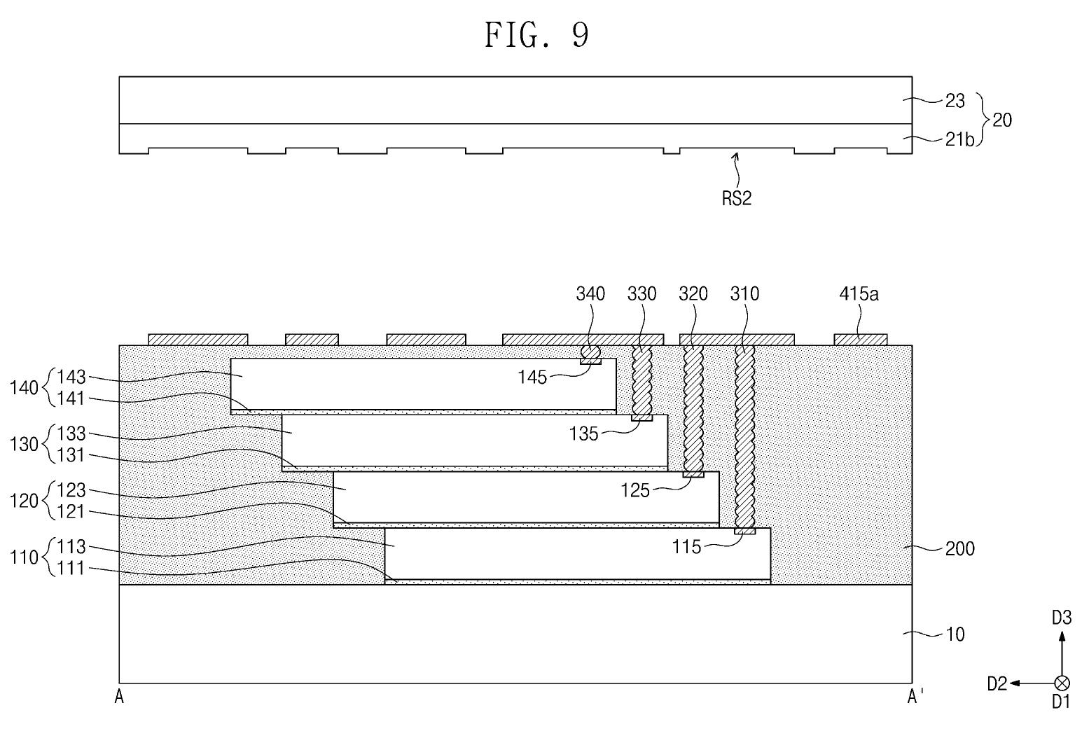

Referring to FIG. 9, the semiconductor manufacturing apparatus 20 may be disposed over the mold layer 200. The semiconductor manufacturing apparatus 20 may include a second mask pattern 21b and the printing apparatus 23. The printing apparatus 23 may be the same as the printing apparatus 23 described with reference to FIGS. 6 and 7. In an embodiment, the second mask pattern 21b may be a stencil mask. A second recess portion RS2 of the second mask pattern 21b may be formed to extend in a direction parallel to a top surface of the carrier substrate 10.

In an embodiment, the conductive ink (not shown) discharged through the printing apparatus 23 may contain a second metal, a second polymer, and solvent. The second metal and the second polymer may be the same as the first metal and the first polymer described above, but the inventive concept is not limited to this example.

In an embodiment, the second metal may include one of copper (Cu), silver (Ag), and gold (Au), and the second polymer may include at least one of polyurethane (PU), polyacrylate, polyethylene glycol (PEG), and polyvinyl alcohol (PVA). For example, the second metal may be dispersed as second metal nanoparticles in the first polymer. The second metal nanoparticles may be connected to one another to allow a current to flow through the conductive ink. The solvent may include one of inorganic or organic solvents. The second polymer may allow metal nanoparticles of the second metal in the conductive ink CI to be uniformly dispersed without clustering together.

A conductive ink (not shown) passing through the second recess portion RS2 may be sprayed onto the mold layer 200 and the first to fourth conductive structures 310, 320, 330, and 340. Thus, the first redistribution lines 415a may be formed on the mold layer 200 and the first to fourth conductive structures 310, 320, 330, and 340. In an embodiment, the printing apparatus 23 may discharge the conductive ink in the form of droplets through the second recess portion RS2 toward the mold layer 200 and the first to fourth conductive structures 310, 320, 330, and 340 to form the first redistribution lines 415a on the mold layer 200 and the first to fourth conductive structures 310, 320, 330, and 340. The first redistribution lines 415a may include a second polymer matrix hardened from the second polymer in the droplets of the conductive ink and second metal nanoparticles of the second metal that are dispersed within the second polymer matrix. The second metal nanoparticles in the second polymer matrix may be connected to one another to allow a current to flow through the first redistribution lines 415a.

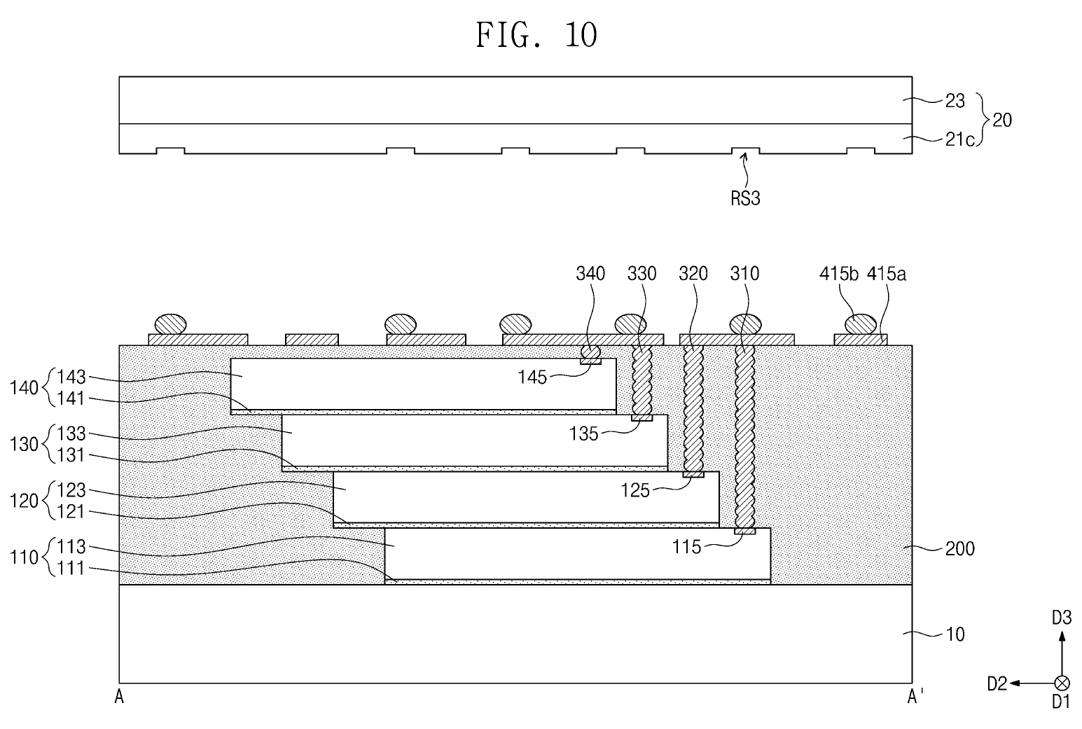

Referring to FIG. 10, the second mask pattern 21b may be removed, and then, a third mask pattern 21c may be disposed on a bottom surface of the printing apparatus 23. In an embodiment, the third mask pattern 21c may be a stencil mask. A third recess portion RS3 of the third mask pattern 21c may vertically overlap the first redistribution lines 415a. The third recess portion RS3 of the third mask pattern 21c may have a circular or elliptical shape, when viewed in a plan view.

The conductive ink (not shown), which is sprayed to form the first redistribution lines 415a, passing through the third recess portion RS3 may be sprayed onto the first redistribution lines 415a. Thus, the first redistribution vias 415b may be formed on the first redistribution lines 415a. In an embodiment, the printing apparatus 23 may discharge the conductive ink in the form of droplets through the third recess portion RS3 toward the first redistribution lines 415a to form the first redistribution vias 415b. The first redistribution vias 415b may be disposed on the first redistribution lines 415a, respectively, and may include the second polymer matrix hardened from the second polymer in the droplets of the conductive ink and the second metal nanoparticles of the second metal that are dispersed within the second polymer matrix. The second metal nanoparticles in the second polymer matrix may be connected to one another to allow a current to flow through the first redistribution vias 415b.

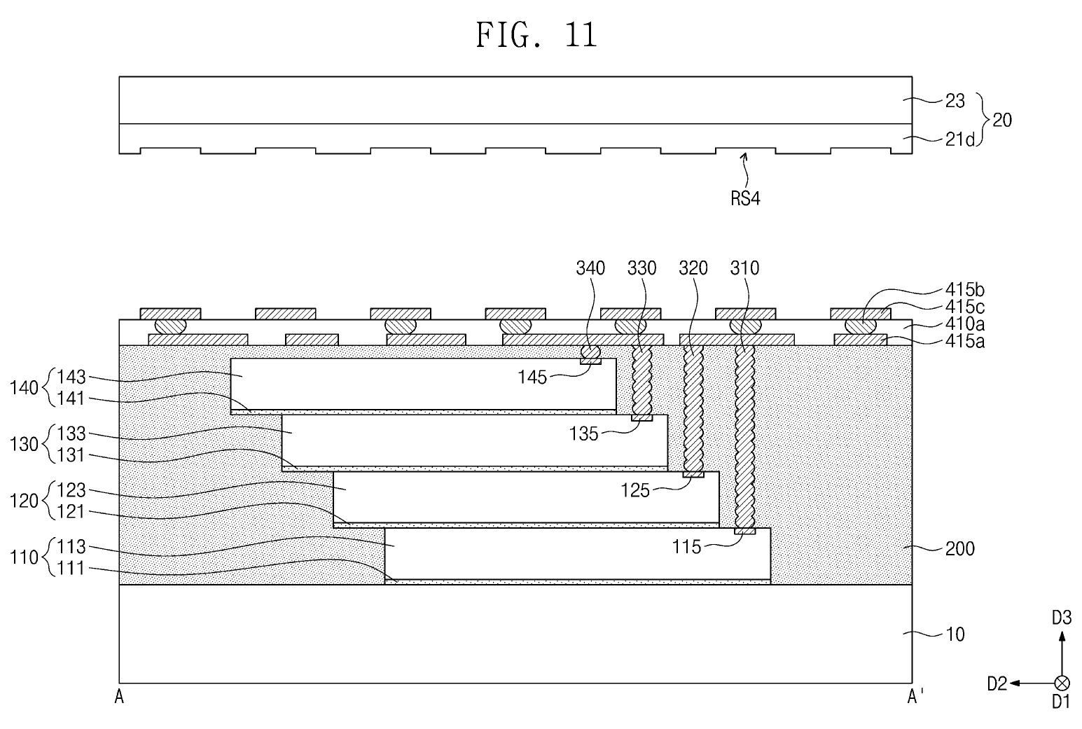

Referring to FIG. 11, the first insulating layer 410a may be formed to cover the first redistribution lines 415a and the first redistribution vias 415b. A grinding process may be performed to expose top surfaces of the first redistribution vias 415b. As a result of the grinding process, upper portions of the first redistribution vias 415b and an upper portion of the first insulating layer 410a may be removed. The semiconductor manufacturing apparatus 20 may be removed during the process of forming the first insulating layer 410a.

The semiconductor manufacturing apparatus 20 may be disposed over the first insulating layer 410a. The semiconductor manufacturing apparatus 20 may include a fourth mask pattern 21d and the printing apparatus 23. The printing apparatus 23 may be the same as the printing apparatus 23 described with reference to FIGS. 9 and 10. In an embodiment, the fourth mask pattern 21d may be a stencil mask. A fourth recess portion RS4 of the fourth mask pattern 21d may be formed to extend in a direction parallel to the top surface of the carrier substrate 10. A portion of the fourth recess portion RS4 may vertically overlap the first redistribution vias 415b.

The conductive ink (not shown), which is sprayed to form the second redistribution lines 415c, passing through the fourth recess portion RS4 may be sprayed onto the first insulating layer 410a. Thus, the second redistribution lines 415c may be formed on the first insulating layer 410a. The second redistribution lines 415c may be electrically connected to the first redistribution vias 415b. In an embodiment, the printing apparatus 23 may discharge the conductive ink in the form of droplets through the fourth recess portion RS4 toward the first redistribution vias 415b to form the second redistribution lines 415c, respectively. The second redistribution lines 415c may be disposed on the first redistribution vias 415b, respectively, and may include the second polymer matrix hardened from the second polymer in the droplets of the conductive ink and the second metal nanoparticles of the second metal that are dispersed within the second polymer matrix.

Referring back to FIG. 2, the semiconductor manufacturing apparatus 20 may be removed. The second insulating layer 410b may be formed on the first insulating layer 410a. Connection terminals 500, which are electrically connected to the second redistribution lines 415c, may be formed. Next, the carrier substrate 10 may be removed.

In an embodiment, the semiconductor manufacturing apparatus 20 including the printing apparatus 23 may be used to form the conductive structures 310, 320, 330, and 340 as well as the redistribution patterns 415. In this case, it may be possible to simplify a process of fabricating a semiconductor package.

According to an embodiment of the inventive concept, conductive structures, which are formed using a thermal ultrasonic printing method, may be used to electrically connect a semiconductor chip to a redistribution substrate. A pitch between the conductive structures formed by the thermal ultrasonic printing method may be smaller than a pitch between wires formed using a capillary apparatus. Thus, chip pads may be formed at a smaller pitch compared to using the capillary apparatus to form chip pads, and in this case, it may be possible to reduce the size of the semiconductor chip and a semiconductor package including the semiconductor chip.

Furthermore, according to an embodiment of the inventive concept, redistribution patterns may be formed by the thermal ultrasonic printing method. Thus, it may be possible to simplify the process of fabricating a semiconductor package.

While example embodiments of the inventive concept have been particularly shown and described, it will be understood by one of ordinary skill in the art that variations in form and detail may be made therein without departing from the spirit and scope of the attached claims.

What is claimed is:

1. A semiconductor package comprising:
a first semiconductor chip including a plurality of first chip pads;
a second semiconductor chip including a plurality of second chip pads and stacked on the first semiconductor chip in a vertical direction perpendicular to a top surface of the first semiconductor chip, wherein the second semiconductor chip exposes a portion of the top surface of the first semiconductor chip;
a mold layer covering the first semiconductor chip and the second semiconductor chip;
a redistribution substrate on the mold layer; and
a first conductive structure penetrating the mold layer in the vertical direction and electrically connected to a corresponding first chip pad among the plurality of first chip pads,
wherein the first conductive structure comprises a plurality of barrel-shaped sections stacked in the vertical direction,
wherein each barrel-shaped section of the plurality of barrel-shaped sections has a convex circumferential side surface, and
wherein the first conductive structure contains a first polymer matrix and a plurality of first metal nanoparticles dispersed within the first polymer matrix.

2. The semiconductor package of claim 1,
wherein, in the first conductive structure, a content of the first polymer matrix has a value in a range of 0.1 wt% to 10 wt%.

3. The semiconductor package of claim 1,
wherein each first metal nanoparticle of the plurality of first metal nanoparticles comprises one of copper (Cu), silver (Ag), and gold (Au), and
wherein the first polymer matrix comprises at least one of polyurethane (PU), polyacrylate, polyethylene glycol (PEG), and polyvinyl alcohol (PVA).

4. The semiconductor package of claim 1,
wherein the first conductive structure overlaps the corresponding first chip pad of the first semiconductor chip in the vertical direction, and
wherein the mold layer contacts the convex circumferential side surface of each barrel-shaped section of the plurality of barrel-shaped sections.

5. The semiconductor package of claim 1,
wherein the plurality of first chip pads of the first semiconductor chip are spaced apart from each other at a first distance in a first horizontal direction parallel to the top surface of the first semiconductor chip, and
wherein the first distance has a value in a range of 10 μm to 40 μm.

6. The semiconductor package of claim 1,
wherein a largest width, in a horizontal direction parallel to the top surface of the first semiconductor chip, of the first conductive structure has a value in a range of 10 μm to 30 μm.

7. The semiconductor package of claim 1, further comprising:
a second conductive structure electrically connected to a corresponding second chip pad among the plurality of second chip pads,
wherein a top surface of the first conductive structure is coplanar with a top surface of the second conductive structure.

8. The semiconductor package of claim 1,
wherein the redistribution substrate comprises:
a plurality of insulating layers disposed on the mold layer, and
a plurality of redistribution patterns disposed in the plurality of insulating layers and electrically connected to the first conductive structure, and
wherein each redistribution pattern of the plurality of redistribution patterns comprises a plurality of second metal nanoparticles and a second polymer matrix in which the plurality of second metal nanoparticles are dispersed.

9. The semiconductor package of claim 8,
wherein each redistribution pattern of the plurality of redistribution patterns comprises a first redistribution line on the mold layer and a first redistribution via on the first redistribution line, and
wherein the first redistribution via has a rounded side surface.

10. A semiconductor package comprising:
a chip stack including a first semiconductor chip;
a mold layer covering the chip stack;
a redistribution substrate including a plurality of insulating layers on the mold layer and a plurality of redistribution patterns in the plurality of insulating layers; and
a first conductive structure extending lengthwise in a vertical direction perpendicular to a top surface of the first semiconductor chip,
wherein the first conductive structure penetrates the mold layer and electrically connects the redistribution substrate to the first semiconductor chip,
wherein the first conductive structure contains a first polymer matrix and a plurality of first metal nanoparticles which are dispersed in the first polymer matrix, and
wherein each redistribution pattern of the plurality of redistribution patterns contains a second polymer matrix and a plurality of second metal nanoparticles which are dispersed in the second polymer matrix.

11. The semiconductor package of claim 10,
wherein each of a first metal nanoparticle of the plurality of first metal nanoparticles and a second metal nanoparticle of the plurality of second metal nanoparticles comprises one of copper (Cu), silver (Ag), and gold (Au), and
wherein each of the first polymer matrix and the second polymer matrix comprises at least one of polyurethane (PU), polyacrylate, polyethylene glycol (PEG), and polyvinyl alcohol (PVA).

12. The semiconductor package of claim 10,
wherein, in the first conductive structure, the first polymer matrix has a content in a range of 0.1 wt% to 10 wt%, and
wherein, in the plurality of redistribution patterns, the second polymer matrix has a content in a range of 0.1 wt% to 10 wt%.

13. The semiconductor package of claim 10,
wherein the plurality of redistribution patterns comprises:
a first redistribution line on the mold layer;
a second redistribution line on the first redistribution line; and
a first redistribution via between the first redistribution line and the second redistribution line, and
wherein the first redistribution via has a rounded side surface connecting a bottom surface of the second redistribution line to a top surface of the first redistribution line.

14. The semiconductor package of claim 13,
wherein the first redistribution via has a largest width at a position between a top end of the first redistribution via and a bottom end thereof, and
wherein the top end and the bottom end contact the second redistribution line and the first redistribution line, respectively.

15. The semiconductor package of claim 13,
wherein the plurality of insulating layers comprise a first insulating layer and a second insulating layer, which are sequentially disposed on the mold layer, and
wherein the first redistribution line and the first redistribution via are disposed in the first insulating layer.

16. The semiconductor package of claim 15,
wherein a top surface of the first redistribution via is coplanar with a top surface of the first insulating layer.

17. A semiconductor package comprising:
a first semiconductor chip including a plurality of first chip pads;
a second semiconductor chip including a plurality of second chip pads and stacked on the first semiconductor chip in a vertical direction perpendicular to a top surface of the first semiconductor chip, wherein the second semiconductor chip exposes a portion of the top surface of the first semiconductor chip;
a mold layer covering the first semiconductor chip and the second semiconductor chip;
a redistribution substrate including a plurality of insulating layers on the mold layer and a plurality of redistribution patterns in the plurality of insulating layers;
a first conductive structure penetrating the mold layer in the vertical direction and electrically connected to a corresponding first chip pad among the plurality of first chip pads; and
a plurality of connection terminals on the redistribution substrate,
wherein a side surface of the first conductive structure comprises a plurality of concave portions and a plurality of convex portions,
wherein each concave portion of the plurality of concave portions and each convex portion of the plurality of convex portions are alternately arranged in the vertical direction,
wherein the first conductive structure contains a first polymer matrix and a plurality of first metal nanoparticles dispersed in the first polymer matrix, and
wherein each redistribution pattern of the plurality of redistribution patterns contains a second polymer matrix and a plurality of second metal nanoparticles dispersed in the second polymer matrix.

18. The semiconductor package of claim 17,
wherein each first metal nanoparticle of the plurality of first metal nanoparticles and each second metal nanoparticle of the plurality of second metal nanoparticles comprise one of copper (Cu), silver (Ag), and gold (Au), and
wherein each of the first polymer matrix and the second polymer matrix comprises at least one of polyurethane (PU), polyacrylate, polyethylene glycol (PEG), and polyvinyl alcohol (PVA).

19. The semiconductor package of claim 17,
wherein the plurality of redistribution patterns comprises:
a first redistribution line on the mold layer;
a second redistribution line on the first redistribution line; and
a first redistribution via between the first redistribution line and the second redistribution line, and
wherein the first redistribution via has a rounded side surface connecting a bottom surface of the second redistribution line to a top surface of the first redistribution line.

20. The semiconductor package of claim 19,
wherein a width of each connection terminal of the plurality of connection terminals is larger than a width of the first redistribution via.
